(19) United States
(12) Patent Application Publication
(10) Pub. No.: US 2009/0021995 A1
(43) Pub. Date: Jan. 22, 2009

(54) Early Write Method and Apparatus

(76) Inventor: Jong-Hoon Oh, Chapel Hill, NC (US)

Correspondence Address: COATS & BENNETT/QIMONDA, 1400 CRESCENT GREEN, SUITE 300, CARY, NC, 27518, US

(21) Appl. No.: 11/780,078

(22) Filed: Jul. 19, 2007

(51) Int. Cl. G11C 7/00

(52) U.S. Cl. 365/189.16; 365/206

(57) ABSTRACT

A write operation is performed in a memory device. During a first stage of the write operation, a signal is applied to gating circuitry at a first voltage level for coupling a data bus line to a bit line when the data bus line is unmasked and for decoupling the data bus line from the bit line when the data bus line is masked. During one or more subsequent stages of the write operation, the signal voltage level is changed for enabling completion of the write operation.

### BACKGROUND OF THE INVENTION

Many types of memory devices store information in an array of memory cells addressable via a row and column address. A row address is decoded to identify the word line containing the desired memory cell while a column address is similarly decoded to identify the bit line containing the desired cell. During a write operation, a bit of data is written to a particular location within the memory array by selecting the word line and bit line at the intersection of which is located the desired memory cell. The bit of data is then written to the selected memory cell. Data is typically written to multiple memory cells during a single write cycle by selecting multiple memory cells within a row.

Conventional memory devices include data input/output (I/O) circuitry for controlling the flow of data into and out of a memory array. The data I/O circuitry typically includes a plurality of bit line sense amplifiers that write data to selected bit lines during a write operation and amplify memory cell data sensed from selected bit lines during a read operation. The data I/O circuitry also includes gating circuitry for coupling particular ones of the sense amplifiers (and thus bit lines) to an internal memory data bus. Conventionally, a column select signal is applied to the gating circuitry which causes the gating circuitry to couple particular sense amplifiers to the data bus. The remaining sense amplifiers are decoupled from the data bus. During write operations, the selected sense amplifiers statically store data sensed from the data bus. The appropriate word and bit lines in the memory array are then activated and the sense amplifiers drive the data into the activated memory cells via the activated bit lines. This way, data is written to or read from memory cells by coupling the appropriate sense amplifiers (and thus bit lines) to the internal memory data bus.

One or more bits of data may be masked during a write operation. Such a write operation is commonly referred to as a masked write operation. A data mask signal received by a memory device indicates whether one or more bits should be masked during a write operation. If so, the masked data bits are not written to the memory array. Instead, bits of data are read from the masked locations in the memory array as if a read operation was being performed, thus refreshing the masked bits. Thus, only unmasked data bits are written to the memory array.

More time is needed to perform a masked write operation than an unmasked write operation because masked bits are read out from the memory array instead of being written to the array. Reading data bits from memory requires additional time for the sense amplifiers to sufficiently amplify the data bit values being sensed before the bit lines can be coupled to the internal data bus by the gating circuitry. Otherwise, the data values may be corrupted if the bit lines are prematurely coupled to the internal data bus. Less cycle time is needed for writing data. The bit lines need only be charged to an acceptable signal level to prevent noise corruption by the gating circuitry before the bit lines can be coupled to the internal data bus during a write operation. Conventional memory devices use the same cycle time for both masked and unmasked write operations even though an unmasked write operation can be completed in less time. Accordingly, memory device performance is reduced when the memory device is used in an environment that does not utilize masked writes.

### SUMMARY OF THE INVENTION

According to the methods and apparatus taught herein, a write operation is performed in a memory device. During a first stage of the write operation, a signal is applied to gating circuitry at a first voltage level for coupling a data bus line to a bit line when the data bus line is unmasked and for decoupling the data bus line from the bit line when the data bus line is masked. During one or more subsequent stages of the write operation, the signal voltage level is changed for enabling completion of the write operation.

Of course, the present invention is not limited to the above features and advantages. Those skilled in the art will recognize additional features and advantages upon reading the following detailed description, and upon viewing the accompanying drawings.

### BRIEF DESCRIPTION OF THE DRAWINGS

FIG. 1 is a block diagram of an embodiment of a memory device including circuitry for reducing the cycle time of unmasked write operations.

FIG. 2 is a block diagram of an embodiment of column decoder circuitry included in the memory device of FIG. 1 for generating a multi-level column select signal.

FIG. 3 is a block diagram of an embodiment of gating and bit line sense amplifier circuitry included in the memory device of FIG. 1.

FIG. 4 is a timing diagram illustrating an exemplary unmasked write operation carried out by the memory device of FIG. 1.

FIG. 5 is a timing diagram illustrating an exemplary masked write operation carried out by the memory device of FIG. 1.

FIG. 6 is a block diagram of an embodiment of circuitry included in the memory device of FIG. 1 for coupling an internal data bus to data buffer circuitry.

### DETAILED DESCRIPTION OF THE INVENTION

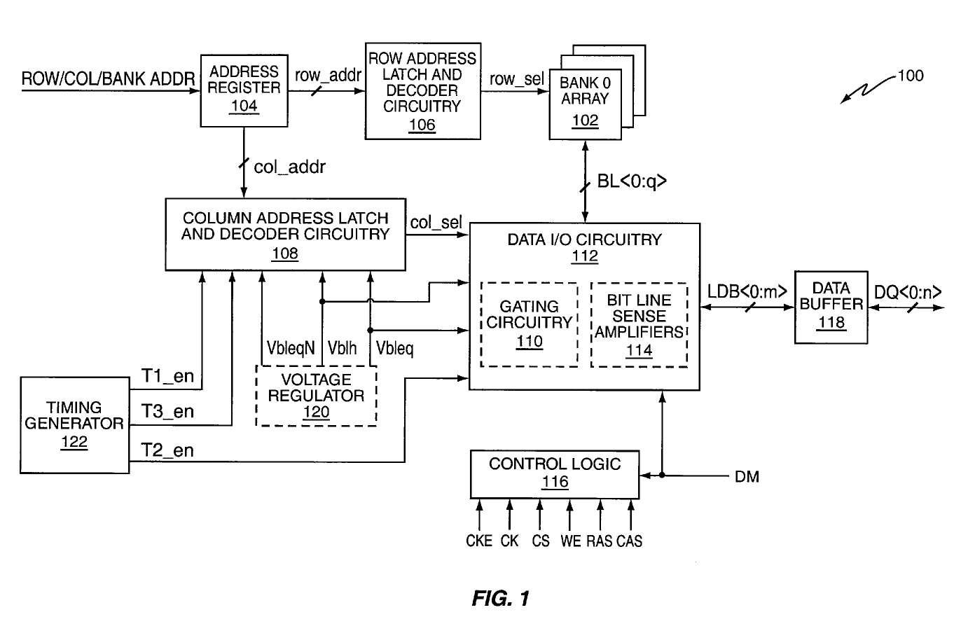

FIG. 1 illustrates an embodiment of a memory device 100 including a memory array 102. The memory array 102 is arranged as one or more banks of memory cells such as Dynamic RAM (DRAM), Ferroelectric RAM (FRAM), Magnetoresistive RAM (MRAM), Phase-change RAM (PRAM) or similar types of cells. Row, column and bank address information (ROW/COUBANK ADDR) received by the memory device 100 is stored in an address register 104. The address information indicates which row and column location in the memory array 102 is to be accessed during a read or write operation (and bank if the memory array is so arranged).

Row address latch and decoder circuitry 106 generates a row select signal (row_sel) based on row address information provided by the address register 104. The row select signal activates a particular word line in the memory array 102, coupling the memory cells in the activated row to their respective bit lines (BL<0:q>). Similarly, column address latch and decoder circuitry 108 generates a column select (col_sel) signal based on column address information provided by the address register 104. The column select signal is applied to gating circuitry 110 included in or associated with data I/O circuitry 112. When activated by the column select signal, the gating circuitry 110 couples an internal data bus (LDB<0:m>) to bit line sense amplifiers 114 included in or associated with the data I/O circuitry 112. The bit line sense amplifiers 114 are also coupled to the memory array bit lines. The bit line sense amplifiers 114 amplify bit line signal levels during read operations and write data to activated bit lines during write operations. This way, data may be read from or written to desired cells in the memory array 102 by activating the appropriate word line via the row select signal and activating the gating circuitry 110 via the column select signal.

The column select signal is driven to at least two different voltage levels during a memory access cycle. During a first stage of the memory access cycle, the column select signal is driven to a first voltage level. The first voltage level is sufficient for causing the gating circuitry 110 to couple the internal data bus lines to the corresponding bit lines when the memory access cycle occurs during an unmasked write operation as will be described in more detail later. The cycle time for an unmasked write operation may thus be reduced because the bit lines begin charging/discharging earlier in the memory access cycle when coupled to the local data bus in response to the first voltage level. However, if the memory operation is a masked write operation, the first voltage level is insufficient for causing the gating circuitry 110 to couple data bus lines to the corresponding bit lines during the first stage of the memory access cycle also as will be described in more detail later. This way, the bit line sense amplifiers 114 are afforded enough time to reliably sense masked data bits read out of the memory array 102 during a masked write operation before the bit lines are coupled to the internal data bus.

In more detail, the memory device 100 also includes control logic 116 for managing overall memory device operation of the memory device 100 responsive to received signals such as a clock enable (CKE), clock (CK), chip select (CS), write enable (WE), row address strobe (RAS), column address strobe (CAS) and the address signals, as is well known in the art. The control logic 116 maintains the current operating mode settings of the memory device 100 and determines what type of memory operation is to be performed when. The memory device 100 also includes a data buffer 118 for capturing data received from an external data bus (DQ<0:n>) as part of a write operation and for holding data to be driven onto the external data bus as part of a read operation. The external data bus may be of the same width as the internal data bus or a different width. Further, the external data bus may operate at the same frequency as the internal data bus or a multiple of the internal bus frequency such as twice the internal bus frequency or higher.

Regardless, the memory device 100 also includes a voltage regulator 120 and timing generator 122. The voltage regulator 120 and timing generator 122 enable proper operation of the memory device 100 during read and write operations. The voltage regulator 120 outputs various reference voltages while the timing generator 122 outputs various enable signals. In one embodiment, at least three reference voltages are output by the voltage regulator 120 (Vblh, Vbleq, and VbleqN) and at least three enable signals are output by the timing generator 122 (T1_en, T2_en, and T3_en). Vblh is provided to both the column decoder circuitry 108 and the data I/O circuitry 112 and is used to drive signal lines to a logic high value. Vbleq is provided to the column decoder circuitry 108 and the data I/O circuitry 112 and is used to precharge signal lines to a desired voltage level during memory operations. The third voltage, VbleqN, is provided to the column decoder circuitry 108. The column decoder circuitry 108 uses Vblh and VbleqN to ramp the column select signal to different voltage levels during read and write operations.

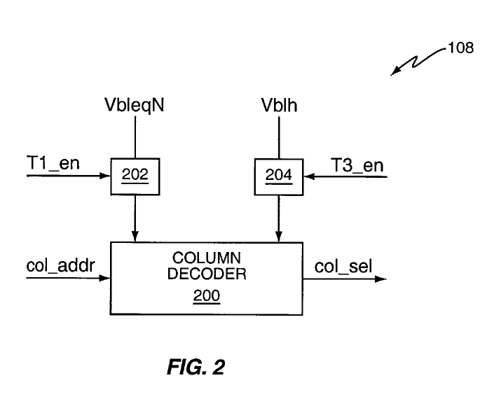

FIG. 2 illustrates an embodiment of the column decoder circuitry 108. A column decoder 200 drives the column select signal to a first voltage level VbleqN during the first stage of a memory access cycle as indicated by T1_en. A first gate 202 couples the VbleqN reference voltage to the column select signal line when T1_en is active. The level of VbleqN is sufficient for coupling internal data bus lines to corresponding bit lines during an unmasked write operation, allowing the bit lines to begin charging/discharging early in the memory access cycle. However, the level of VbleqN is not sufficient for coupling the data bus lines to the bit lines during the first stage of the memory access cycle when the memory access cycle occurs during a masked write operation.

During the second stage of the memory access cycle as indicated by T3_en, the column decoder 200 drives the column select signal to a second voltage level Vblh. A second gate 204 couples Vblh to the column select signal line when T3_en is active. The ongoing memory operation reliably completes when the column select signal is driven to Vblh. The enable signal T2_en indicates to the data I/O circuitry 112 when the bit line sense amplifiers 114 are to be activated during a read or write operation.

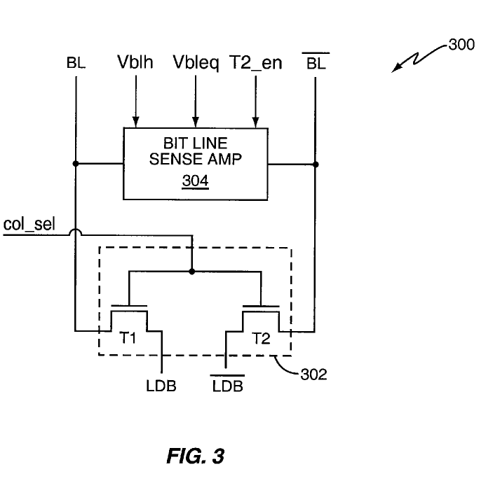

FIG. 3 illustrates an embodiment of bit line sense amplifier and gating circuitry 300 associated with one bit of the data bus and a corresponding bit line of the memory array 102. The circuitry 300 of FIG. 3 may be extended to all bits of the data bus and the memory array bit lines. According to this embodiment, gating circuitry 302 comprises two n-MOS transistors T1 and T2. However, the gating circuitry 302 may comprise other types of transistors such as p-MOS transistors. When enabled, the n-MOS transistors T1 and T2 couple a differential data bus line pair (LDB/ L̅D̅B̅) to the corresponding differential bit line pair (BL/ B̅L̅) and bit line sense amplifier.

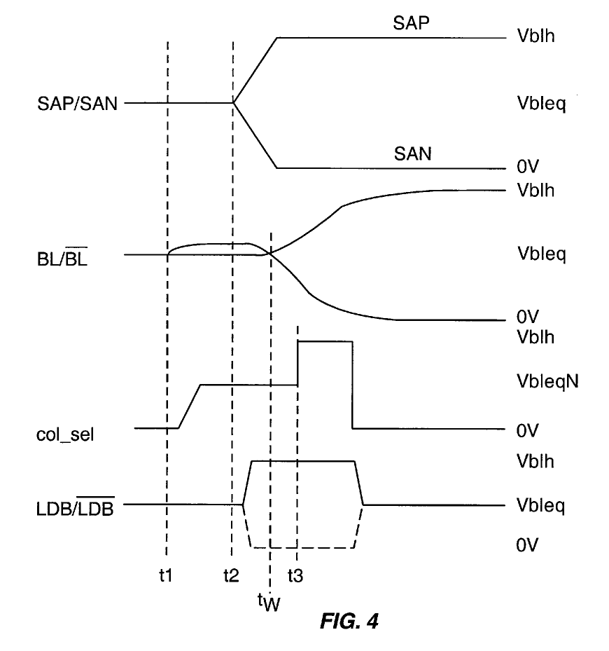

Operation of the gating circuitry 302 and bit line sense amplifier 304 during an unmasked write operation is described next with reference to the timing diagram illustrated in FIG. 4. Before the write cycle begins, the bit line pair and data bus line pair are both pre-charged to a desired signal level, e.g., Vbleq in one embodiment. When the unmasked write cycle begins at time t1, the memory cell (not shown) coupled to the bit line pair begins charging one of the differential bit lines. The differential bit line charged by the memory cell depends on the state of the memory cell. For illustrative purposes only, FIG. 4 shows signal transitions when the memory cell initially stores a logic one. Accordingly, the memory cell charges differential bit line BL to a voltage level slightly above the pre-charged level, e.g., to approximately Vbleq+100 mV or less. If the memory cell stored a logic zero, differential bit line B̅L̅ would be charged to the slightly elevated voltage level. Either way, one of the differential bit lines is charged to a voltage level slightly elevated above the pre-charged level upon activation of the memory cell.

The column select signal is then driven to a first voltage level after sufficient time has elapsed from when the memory cell was first coupled to the bit line pair BL/ B̅L̅. In one embodiment, the column select signal is driven to the voltage level VbleqN when the T1_en signal is activated by the timing generator 122. The amount of time elapsed before the column select signal is activated depends on the memory technology and the application for which the memory device 100 is targeted. As such, the column select signal may be driven to a first voltage level after any desired amount of time has elapsed from when the memory cell was first coupled to the bit line pair. Preferably, the column select signal is driven to the first voltage level after one of the complimentary bit lines charges to a signal level sufficient to prevent noise produced by the gating circuitry 302 from corrupting the data value carried by the bit line pair.

Initially, both n-MOS transistors T1 and T2 are switched off because both the data bus line pair and bit line pair are pre-charged to the same voltage level (Vbleq in this embodiment). Accordingly, the gate-to-source voltage of both transistors T1 and T2 is not high enough to switch on either device. The bit line sense amplifier 304 is eventually activated at time t2. In one embodiment, the sense amplifier 304 is activated when the timing generator 122 activates the T2_en signal. The sense amplifier 304 activates when the sense amplifier supply voltages (SAN/SAP) are tied to a positive voltage source (Vblh in this embodiment) and ground. When activated, the bit line sense amplifier 304 detects the small voltage difference between the differential bit line pair and amplifies it by beginning to drive the bit lines pair to opposing logic levels (Vblh and 0V in FIG. 4).

Eventually, the local data bus line pair is charged to a signal level representing the data bit value to be written into the memory array 102. When the column select signal is charged to the first voltage level and the local data bus line pair is driven from its pre-charged state, one of the n-MOS transistors T1 or T2 switches on, coupling its differential data bus line to the corresponding differential bit line. Of course, the n-MOS transistor that switches on depends on whether the data bus line pair carries a logic zero or logic one data value. In the embodiment shown in FIG. 4, LDB is driven to a logic zero value (0V) while the complimentary bus line L̅D̅B̅ is driven to a logic one value (Vlbh). Accordingly, the gate to source voltage of transistor T1 is high enough to turn on the device. That is, the slightly elevated signal level present at bit line BL is sufficient to switch on transistor T1 when LDB is driven to ground. As a result, transistor T1 couples LDB to BL. If a logic one were being written instead of a logic zero, transistor T2 would couple L̅D̅B̅ to B̅L̅. Of course, the reverse holds true for p-MOS logic.

Preferably, the column select signal is driven to the first voltage level before the data bus line pair is driven from its pre-charged state. This way, one of the transistors T1 or T2 switches on with minimal delay in response to the corresponding differential data bus line reaching a sufficient signal level. However, activation of the column select signal may be delayed until after the data bus line pair is driven out of its pre-charged state.

Either way, the data bus line pair LDB/ L̅D̅B̅ causes the bit line pair BL/ B̅L̅ to begin toggling from a logic one value to a logic zero value before the column select signal is driven to a higher voltage level, e.g., to Vblh in one embodiment. The bit line toggle point is indicated by t_{w} in FIG. 4. The column select signal in a conventional memory device is not driven to two different voltage levels at different stages of a memory access cycle. Instead, a conventional column select signal is driven to a single high voltage level such as Vblh later in the memory cycle for both masked and unmasked write operations, thus yielding the same memory access cycle time for both types of memory operations.

According to the embodiments disclosed herein, a quicker bit line toggle point results for unmasked write operations when the local data bus is coupled to the array bit lines before the column select signal is driven to a higher voltage level later in the write cycle. The memory access cycle time for unmasked write operations may be shortened when the bit line toggle point occurs earlier in time, e.g., as indicated by t_{w} in FIG. 4. The column select signal is driven to the higher voltage level during the second stage of the memory access cycle (at time t3 in FIG. 4) to enable completion of the unmasked write.

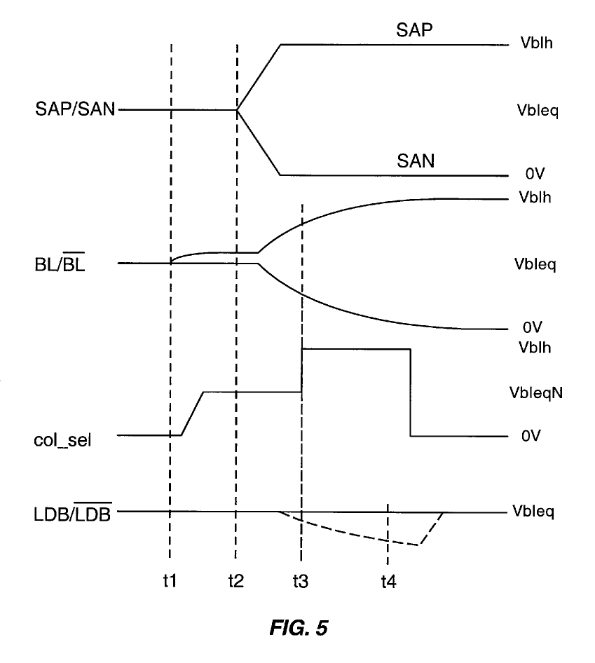

Operation of the gating circuitry 302 and bit line sense amplifier 304 during a masked write operation is described next with reference to the timing diagram illustrated in FIG. 5. The signal transitions and levels shown in FIG. 5 are similar to those shown in FIG. 4, except that the data bus line pair LDB/ L̅D̅B̅ remains at the pre-charged level (e.g., Vbleq) during a masked write operation. The differential data bus lines remain at the pre-charged level because the data bit represented by the lines is masked, and thus not written to the memory array during the write operation. Instead, the data value stored by the memory cell coupled to the masked bit line pair is read-out from the memory array 102 as if a read operation was being performed.

Notably, the gate to source voltage of both n-MOS transistors T1 and T2 is not sufficient to turn on either device when the data bus line pair LDB/ L̅D̅B̅ remains at the pre-charged level. The memory cell coupled to the corresponding bit line pair BL/ B̅L̅ charges one of the differential bit lines to a voltage level slightly above the pre-charged level as previously described. Neither the slightly elevated bit line voltage nor the pre-charged level of the data bus line pair is sufficient to switch on either transistor T1 or T2 when the column select signal is at the first voltage level, e.g., VbleqN in one embodiment.

As such, neither of the differential data bus lines is coupled to its corresponding bit line when the data bit represented by the differential bus lines is masked. This allows the bit line sense amplifier 304 to amplify the bit line data value without disturbance from the data bus line pair. Eventually, the column select signal is driven to a higher voltage level at t3 in FIG. 5 so that the masked write operation can be completed. In one embodiment, the column select signal is driven to Vbleq when the timing generator 122 activates the T3_en signal. The amplified bit line data value may then be read out by a read sense amplifier (not shown) included in or associated with the data I/O circuitry 112.

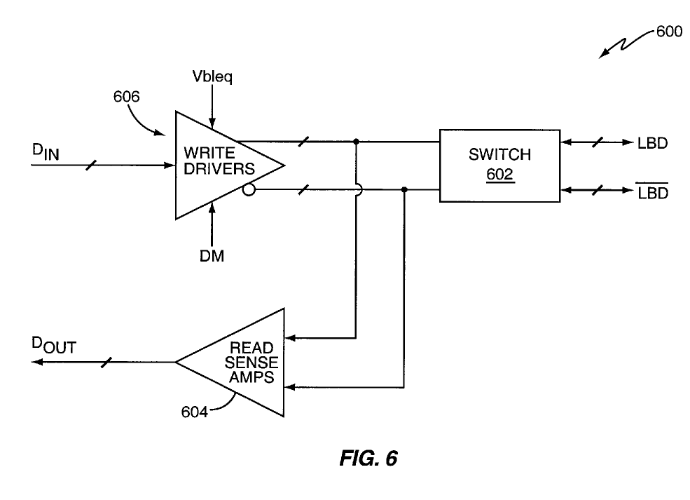

FIG. 6 illustrates an embodiment of circuitry 600 included in or associated with the data I/O circuitry 112. The circuitry 600 drives data onto the local data bus during write operations and reads data from the local data bus during read operations. A switch 602 controls when the circuitry 600 is coupled to the local data bus. Sense amplifier circuitry 604 reads data from the local data bus during read operations and provides the amplified data to the data buffer 118 for driving off-chip. The sense amplifier circuitry 604 may also read masked data bits during masked write operations. Write driver circuitry 606 receives data from the write buffer 118 during write operations and drives the data onto the local data bus. One or more bits may be masked during a write operation, and thus remain in a pre-charged state. In one embodiment, the write driver circuitry 606 maintains masked data bits at the Vbleq voltage level during masked write operations as indicated by a data mask signal (DM) received by the memory device 100.

With the above range of variations and applications in mind, it should be understood that the present invention is not limited by the foregoing description, nor is it limited by the accompanying drawings. Instead, the present invention is limited only by the following claims and their legal equivalents.

What is claimed is:

1. A method of performing a write operation in a memory device, comprising:
during a first stage of the write operation, applying a signal to gating circuitry at a first voltage level for coupling a data bus line to a bit line when the data bus line is unmasked and for decoupling the data bus line from the bit line when the data bus line is masked; and
during one or more subsequent stages of the write operation, changing the signal voltage level for enabling completion of the write operation.

2. The method of claim 1, wherein applying the signal to the gating circuitry at a first voltage level comprises applying the signal at a voltage level sufficient to enable the gating circuitry when the data bus line is unmasked and to disable the gating circuitry when the data bus line is masked.

3. The method of claim 2, wherein driving the signal to a voltage level sufficient to enable the gating circuitry when the data bus line is unmasked and to disable the gating circuitry when the data bus line is masked comprises driving the signal to a voltage level sufficient to switch on n-MOS logic configured to couple the data bus line to the bit line when the data bus line is at a logic low level and to switch off the n-MOS logic when the data bus line is masked.

4. The method of claim 1, wherein applying the signal to the gating circuitry at a first voltage level comprises applying the signal at the first voltage level after the bit line charges to a signal level sufficient to prevent noise produced by the gating circuitry from corrupting the bit line signal.

5. The method of claim 1, wherein applying the signal to the gating circuitry at a first voltage level comprises applying the signal at the first voltage level before the data bus line is driven from a pre-charged level to a data signal level.

6. The method of claim 1, wherein changing the signal voltage level during the one or more subsequent stages of the write operation comprises:
changing the signal voltage level after the bit line is driven to a desired signal level by the data bus line when the data bus line is unmasked; and
changing the signal voltage level after the bit line reaches a desired signal level for sensing when the data bus line is masked.

7. A memory device, comprising:
signal generation circuitry configured to output a signal at a first voltage level during a first stage of a write operation and to change the signal voltage level during a subsequent stage of the write operation; and
gating circuitry configured to:
couple a data bus line to a bit line when the data bus line is unmasked, responsive to the signal output by the signal generation circuitry during the first stage of the write operation;
decouple the data bus line from the bit line when the data bus line is masked, responsive to the signal output by the signal generation circuitry during the first stage of the write operation; and
enable completion of the write operation responsive to the signal output by the signal generation circuitry during the subsequent stage of the write operation.

8. The memory device of claim 7, wherein the signal generation circuitry is configured to output the signal during the first stage of the write operation signal at a voltage level sufficient to enable the gating circuitry when the data bus line is unmasked and to disable the gating circuitry when the data bus line is masked.

9. The memory device of claim 7, wherein the gating circuitry comprises n-MOS logic configured to:
couple the data bus line to the bit line when the data bus line is at a logic low level responsive to the signal output by the signal generation circuitry during the first stage of the write operation; and
decouple the data bus line from the bit line when the data bus line is masked responsive to the signal output by the signal generation circuitry during the first stage of the write operation.

10. The memory device of claim 7, wherein the signal generation circuitry is configured to output the signal at the first voltage level after the bit line charges to a signal level sufficient to prevent noise produced by the gating circuitry from corrupting the bit line signal.

11. The memory device of claim 7, wherein the signal generation circuitry is configured to output the signal at the first voltage level before the data bus line is driven from a pre-charged level to a data signal level.

12. The memory device of claim 7, wherein the signal generation circuitry is configured to:
change the signal voltage level during the subsequent stage of the write operation after the bit line is driven to a desired signal level by the data bus line when the data bus line is unmasked; and
change the signal voltage level during the subsequent stage of the write operation after the bit line reaches a desired signal level for sensing when the data bus line is masked.

13. A memory device, comprising:
means for outputting a signal at a first voltage level during a first stage of a write operation and for changing the signal voltage level during a subsequent stage of the write operation; and
gating circuitry configured to:
couple a data bus line to a bit line when the data bus line is unmasked responsive to the signal output by the signal generation circuitry during the first stage of the write operation;
decouple the data bus line from the bit line when the data bus line is masked responsive to the signal output by the signal generation circuitry during the first stage of the write operation; and
enable completion of the write operation responsive to the signal output by the signal generation circuitry during the subsequent stage of the write operation.

14. A method of writing information to a memory device, comprising:
coupling a data bus line to a bit line during a first stage of a memory access cycle when the memory access cycle occurs during an unmasked write operation;
decoupling the data bus line from the bit line during the first stage of the memory access cycle when the memory access cycle occurs during a masked write operation; and
completing either one of the write operations during a subsequent stage of the memory access cycle, wherein the memory access cycle is shorter for the unmasked write operation than for the masked write operation.

15. The method of claim 14, wherein coupling a data bus line to a bit line during a first stage of a memory access cycle when the memory access cycle occurs during an unmasked write operation comprises enabling gating circuitry configured to couple the data bus line to the bit line when enabled.

16. The method of claim 15, wherein enabling the gating circuitry comprises switching on n-MOS logic responsive to the data bus line reaching a logic low level during the first stage of the memory access.

17. The method of claim 14, wherein decoupling the data bus line from the bit line during the first stage of the memory access cycle when the memory access cycle occurs during a masked write operation comprises disabling gating circuitry configured to couple the data bus line to the bit line when enabled.

18. The method of claim 17, wherein disabling the gating circuitry comprises switching off n-MOS logic responsive to the data bus line being masked during the first stage of the memory access.

19. A memory device comprising gating circuitry configured to:
couple a data bus line to a bit line during a first stage of a memory access cycle when the memory access cycle occurs during an unmasked write operation;
decouple the data bus line from the bit line during the first stage of the memory access cycle when the memory access cycle occurs during a masked write operation; and
enable completion of either one of the write operations during a subsequent stage of the memory access cycle, wherein the memory access cycle is shorter for the unmasked write operation than for the masked write operation.

20. The memory device of claim 19, wherein the gating circuitry comprises n-MOS logic configured to couple the data bus line to the bit line responsive to the data bus line reaching a logic low level during the first stage of the memory access cycle.

21. The memory device of claim 19, wherein the gating circuitry comprises n-MOS logic configured to decouple the data bus line from the bit line responsive to the data bus line being masked during the first stage of the memory access cycle.
